(19) United States
(12) Patent Application Publication
(10) Pub. No.: US 2012/0048343 A1
(43) Pub. Date: Mar. 1, 2012

(54) OUTDOOR BASE STATION HOUSE HAVING THIN FILM SOLAR CELLS

(75) Inventors: YEE SHYI CHANG, TAIPEI (TW); CHANG CHI MEI, TAIPEI (TW); CHI-JEN LIU, TAIPEI (TW)

(73) Assignee: AN CHING NEW ENERGY MACHINERY & EQUIPMENT CO.,LTD., TAIPEI (TW)

(21) Appl. No.: 13/017,441

(22) Filed: Jan. 31, 2011

(30) Foreign Application Priority Data
Aug. 25, 2010 (TW) 99128517

(51) Int. Cl. H01L 31/048; H01M 10/46

(52) U.S. Cl. 136/251; 165/48.2; 320/101

(57) ABSTRACT

An outdoor base station house having thin film solar cells, comprising: a sentry-box-shaped building body, at least a thin film solar cell, and a power source module. Said sentry-box-shaped building body is provided with a top portion, and said thin film solar cells are arranged on said top portion of said sentry-box-shaped building body. Said thin film solar cells absorb green light, blue light, and ultraviolet light, and convert them into electrical energy, and reflect part of infrared light and said ultraviolet light that are not absorbed. Red light, orange light, yellow light pass through said thin film solar cells and reach inside of said sentry-box-shaped building body. Said power source module is disposed inside said sentry-box-shaped building body, and stores electrical energy converted by thin film solar cells for supplying it to a wireless communication base station.

### BACKGROUND OF THE INVENTION

1. Field of the Invention

The present invention relates to a base station house for setting up a medium-or-large size wireless communication base station, and in particular to an outdoor base station house having thin film solar cell for regulating indoor temperature and lighting in achieving energy conversation.

2. The Prior Arts

Along with the global concern about environment protection, and worldwide acceptance and implementation of the concept of “energy conservation and carbon reduction”, therefore, the development and utilization of regenerated energy resources has been the keypoint of development for various countries of the world. Among the regenerated energy resources, solar energy and solar cell capable of converting sunlight into electrical energy are of the most promising energy industry, since sunlight is available all over the world, and it would not create pollution to the Earth like other energy resources (such as nuclear energy, and petrochemical energy).

In case that the solar cell is provided with a large light irradiating area, then it can produce relatively large amount of electrical energy for use by various devices. Therefore, quite a lot of manufacturers hope to incorporate the energy saving concept into daily life of ordinary people, such as utilizing reusable solar cell in replacing the conventional disposable battery cells, so as to reduce pollution to the environment. In addition, the concept of “green energy building” can be combined with the solar cell, namely, putting solar cells in a building, where they are most exposed and irradiated by sunlight, such that the electrical energy generated by solar cell can be used to compensate for the electrical energy consumed by the building. Presently, solar energy is most needed for industries requiring thermostatic indoor conditions, such as houses of sophisticated agriculture and communication server.

Moreover, solar energy is most needed for an outdoor base station house for regulating indoor temperature and lighting in achieving objective of energy conversation, and in this respect, the conventional outdoor base station house has much room for improvement.

### SUMMARY OF THE INVENTION

In view of the problems and shortcomings of the prior art, the present invention provides an outdoor base station house having thin film solar cell disposed on a top portion of its building body for regulating indoor temperature and lighting in achieving objective of energy conversation.

The present invention provide an outdoor base station house, comprising a sentry-box-shaped building body, at least a thin film solar cell, and a power source module. The sentry-box-shaped building body has a top portion, and the thin film solar cell is arranged on the top portion of the sentry-box-shaped building body. The thin film solar cell is capable of absorbing green light, blue light, and ultraviolet light in the sunlight, converting them into electrical energy, and reflecting part of the infrared light and ultraviolet light that are not absorbed. Red light, orange light, yellow light will pass through the thin film solar cell and reach inside of the sentry-box-shaped building body, so as to provide the illumination as required. The power source module is located inside the sentry-box-shaped building body for storing the electrical energy converted and obtained by the thin film solar cell, and supplying the electrical energy to the wireless communication base station.

In an embodiment of the present invention, the top portion of the sentry-box-shaped building body is a detachable and replaceable roof structure, such that thin film solar cells can easily be replaced.

In another embodiment of the present invention, the power source module includes a power supply device and a power storage device. The power storage device is used to store the electricity supplied by the power supply device and the electricity converted by the thin film solar cells, and supply the electricity to the wireless communication base station. In the present embodiment, the power storage device can be an uninterrupted power supply (UPS).

In a yet another embodiment of the present invention, the outdoor base station house may further include an air conditioner disposed in the sentry-box-shaped building body, and it regulates the temperature inside the sentry-box-shaped building body, with its power supplied by the power source module.

In a still another embodiment of the present invention, the top portion of the sentry-box-shaped building body is provided with eaves made of thin film solar cells, for shielding outside winds and rains.

In a further embodiment of the present invention, the outside base station house further includes a plurality of light-emitting-diodes (LEDs), arranged on the top portion of the sentry-box-shaped building body, for providing illumination light beams in irradiating inside the building body. The thin film solar cells are connected electrically to the LEDs, so as to supply the converted electricity to LEDs as required.

In a yet another embodiment of the present invention, the sentry-box-shaped building body is of a steel frame structure, and thin film solar cells are arranged on the top portion of the sentry-box-shaped building body and its perimeter. Moreover, in some of the embodiments, the thin film solar cells are transparent solar cells.

As mentioned above, in the embodiment of the present invention, in the outdoor base station house, thin film solar cell are arranged on the top portion of the building body, so that when irradiated by sunlight, the thin film solar cell absorbs the green light, blue light, and ultra-violet light contained therein, and converts them into electrical energy, for supplying it to a power storage device, an air conditioner, or a wireless communication base station in the outdoor base station house, thus achieving energy conservation and saving the expense spent on electricity.

In addition, since some of the infrared light and ultraviolet light are reflected by the thin film solar cell, the rate of temperature increase inside the outdoor base station house can be reduced, thus the internal temperature can be regulated effectively in cooperation with an air conditioners, hereby saving the expense of electricity for the air conditioner. Red light, orange light, yellow light passing through the thin film solar cell will reach inside of the sentry-box-shaped building body in providing the illumination as required.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of an outdoor base station house having thin film solar cells according to the first embodiment of the present invention; and

FIG. 2 is a schematic diagram of an outdoor base station house having thin film solar cells according to the second embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

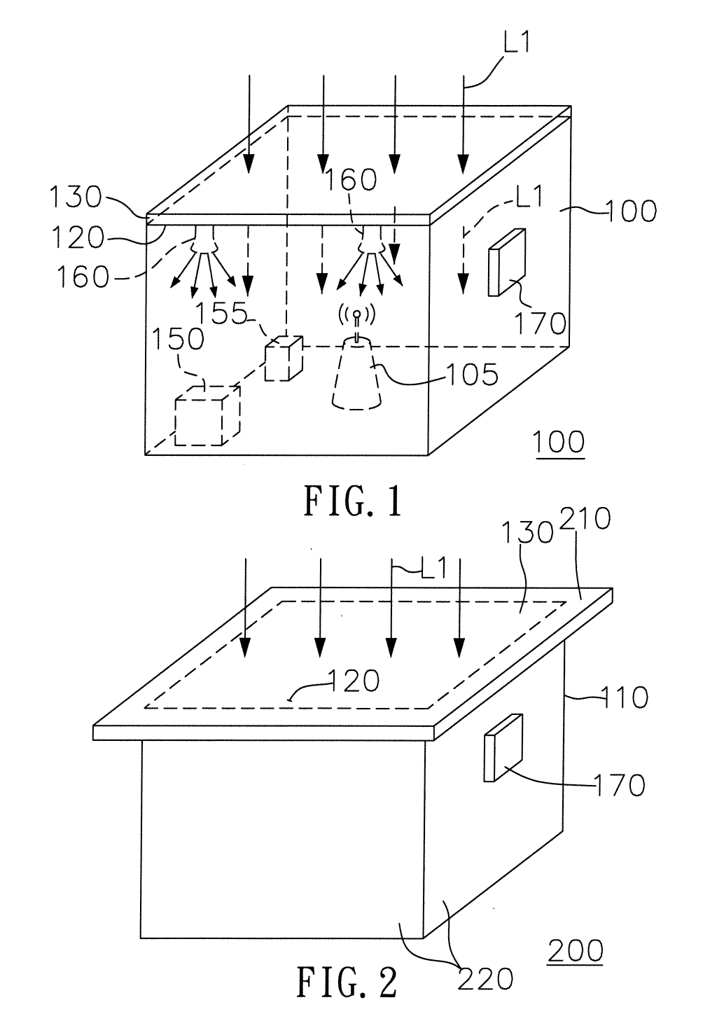

Refer to FIG. 1 for a schematic diagram of an outdoor base station house having thin film solar cells according to the first embodiment of the present invention. As shown in FIG. 1, the outdoor base station house 100 is used to accommodate a wireless communication base station 105, which usually is placed on top of higher and bigger building to ensure better communication effects, and the outdoor base station house 100 is able to protect the wireless communication base station 105 from the damages of rain or strong wind. Power source module 150 provides the power required for the wireless communication base station 105, which is located in the lower portion of the outdoor base station house 100. To be more specific, the outdoor base station house 100 of the present embodiment includes a sentry-box-shaped building body 110, at least a thin film solar cell 130, and a power source module 150. The sentry-box-shaped building body 110 has a size similar to a building structure of an outdoor guard post, and it provides a space for a person to stand inside, so that maintenance personnel may get in to perform installation, repair, and maintenance of wireless communication base station 105. In the present embodiment, the sentry-box-shaped building body 110 is set up into a steel frame structure, so as to define a space inside the building body.

Refer again to FIG. 1, wherein, sentry-box-shaped building body 110 is provided with a top portion 120, and thin film solar cell 130 is arranged on the top portion 120 of the sentry-box-shaped building body 110. In the present embodiment, power source module 150 can be an uninterrupted power supply (UPS), that is connected electrically to a power supply socket; meanwhile, it may also store the electrical energy converted by the thin film solar cells 130 for supplying it to the wireless communication base station. Moreover, the outdoor base station house 100 may also include a power supply device 155 (in the present embodiment, a diesel-fuel generator is taken as an example), so that when the power supply is interrupted, the power supply device 155 can be activated immediately to supply the power required, so as to maintain the normal operations of the wireless communication base station 105.

To be more specific, in the present embodiment, the major characteristic of the thin film solar cells 130 is that, when sunlight L1 irradiates onto the top portion 120 of the building body 110, the thin film solar cells 130 provided therein will absorb the green light, blue light, and ultraviolet light in sunlight L1 and convert them into electrical energy. In addition, the thin film solar cells 130 will reflect part of the infrared light and ultraviolet light that can not be absorbed, such that the temperature inside the building body 110 is not apt to increase, so as to make it cooler and comfortable. Red light, orange light, yellow light, and infrared light in sunlight L1 will pass through the thin film solar cells 130 and reach inside of the building body 110 (for example, as shown in dashed line L1 in FIG. 1), and provide the illumination required. In other words, in the present embodiment, the thin film solar cell 120 can be a transparent solar cell, such that red light, orange light, yellow light, and infrared light in sunlight L1 are apt to pass through the thin film solar cells 130, yet green light, blue light, and ultraviolet light in sunlight L1 are apt to be absorbed or reflected by the thin film solar cells 130.

In the present embodiment, some of the equipment in the outdoor base station house 100 can not maintain normal operations in high temperature, for example, the uninterrupted power supply (UPS) 150, the power supply device 155, and the medium-or-large size wireless communication base station 105. Therefore, in an outdoor base station house 100, an air conditioner 170 is required to be in a sentry-box-shaped building body 110 to regulate its inner temperature. In this respect, power source module 150 and the thin film solar cells 130 may supply power to the air conditioner 170, so as to save air conditioning expense on electricity.

In the present embodiment, the top portion 120 of the sentry-box-shaped building body 110 can be a detachable and replaceable roof structure, such that it is easy to replace any damaged or worn out thin film solar cells 130 on the top portion 120. In addition, the entire structure of outdoor base station house 100 can be designed into a modular configuration, so as to facilitate the assembly, installation, and transportation of wireless communication base station 105. Moreover, the outdoor base station house 100 is also provided with a plurality of light-emitting-diodes 160 on the top portion of the building body 110, such that when in sunny weather and broad daylight, the portion of sunlight L1 passing through the transparent thin film solar cells 130 can be used for internal illumination of a sentry-box-shaped building body 110; and while in cloudy weather or at night, light-emitting-diodes 160 can replace light bulbs in providing sufficient illumination inside the building body 110, so that maintenance people may carry on repair and/or maintenance for the wireless communication base station 105 at night.

Furthermore, thin film solar cells 130 may also be connected electrically to the light-emitting-diodes 160 for providing it with the converted electricity. To be more specific, when in sunny weather and broad daylight, the portion of sunlight L1 passing through the thin film solar cells 130 can provide illumination inside the building body 110; and while in cloudy weather or at night, light-emitting-diodes 160 can provide sufficient illumination inside the building body 110, with its power provided by ordinary local power supply, in addition, the power stored in power source module 150 mentioned above can also be utilized, so as to save the local power supply utilized, in achieving “energy conservation and carbon reduction”.

It is worth mentioning that, in another embodiment, the thin film solar cells 130 can be made into eaves on the top portion 120 of the sentry-box-shaped building body 110, to protect it from rain and strong wind. Refer to FIG. 2 for a schematic diagram of an outdoor base station house having thin film solar cells according to a second embodiment of the present invention. As shown in FIG. 2, the top portion 120 of the building body 110 is extended outward to form an eaves portion 210, that is made of thin film solar cells 130 on as to increase light receiving area and photoelectric conversion efficiency. Moreover, it can also provide shelter against rain and strong wind, so that maintenance staff may carry on their work smoothly. In the present embodiment, steel frame structures are put around perimeter of the building body 110 as the support building body, and thin film solar cells 130 are put on the outer portion 220 around the building body 110 (as shown by slant line in FIG. 2), so as to increase the light receiving area of sunlight L1 and the photoelectric conversion efficiency of the thin film solar cells 130.

Summing up the above, in the present embodiment, thin film solar cells are arranged on the top portion of building body, such that when sunlight irradiates on the top portion of the building, the thin film solar cells absorb the green light, blue light, and ultraviolet light in the sunlight, and convert them into electrical energy, and then provide it to the power storage device, air conditioner, or wireless communication base station, etc. in the outdoor base station house, so as to save expense spent on electricity.

In addition, since some of the infrared light and ultraviolet light are reflected by the thin film solar cell, the rate of temperature increase inside the outdoor base station house can be reduced, thus its internal temperature can be regulated effectively in cooperation with an air conditioner. Red light, orange light, yellow light passing through the thin film solar cell will reach inside of the sentry-box-shaped building body in providing the illumination as required.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. An outdoor base station house having thin film solar cells, comprising:
an sentry-box-shaped building body, having a top portion;
at least a thin film solar cell, arranged on said top portion of said sentry-box-shaped building body, said thin film solar cell absorbs green light, blue light, and ultraviolet light in sunlight, and converts them into electric energy, and reflects infrared light and a part of said ultraviolet light, such that red light, orange light, and yellow light pass through said thin film solar cell, and reach inside of said sentry-box-shaped building body; and
a power source module, disposed inside said sentry-box-shaped building body, and is used to store electrical energy converted by said thin film solar cell, and supply said electrical energy to a wireless communication base station.

2. The outdoor base station house having thin film solar cells as claimed in claim 1, wherein said top portion of said sentry-box-shaped building body is a detachable and replaceable roof, so as to replace said thin film solar cells.

3. The outdoor base station house having thin film solar cells as claimed in claim 1, wherein said power source module comprises: a power storage device, used to store electrical energy converted by said thin film solar cells, and supply said electrical energy to said wireless communication base station.

4. The outdoor base station house having thin film solar cells as claimed in claim 3, wherein said power source module further comprising: a power supply device, used to supply electrical energy to said wireless communication base station.

5. The outdoor base station house having thin film solar cells as claimed in claim 3, wherein said power storage device is an uninterrupted power supply (UPS).

6. The outdoor base station house having thin film solar cells as claimed in claim 1, further comprising: an air conditioner, disposed on said sentry-box-shaped building body, so as to regulate temperature inside said sentry-box-shaped building body, said air conditioner is connected electrically to said thin film solar cell, such that it is supplied with electrical energy converted by said thin film solar cell.

7. The outdoor base station house having thin film solar cells as claimed in claim 1, wherein said top portion of said sentry-box-shaped building body is provided with eaves formed by said thin film solar cells.

8. The outdoor base station house having thin film solar cells as claimed in claim 1, further comprising: at least a light-emitting-diode, arranged on said top portion of said sentry-box-shaped building body, and it provides illumination light beams irradiating inside of said building body, said light-emitting-diode is connected electrically to said thin film solar cell, such that it is supplied with electrical energy converted by said thin film solar cell.

9. The outdoor base station house having thin film solar cells as claimed in claim 1, wherein said sentry-box-shaped building body is made of a steel frame structure.

10. The outdoor base station house having thin film solar cells as claimed in claim 1, wherein said thin film solar cell is transparent solar cell.
